(19) United States
(12) Patent Application Publication
(10) Pub. No.: US 2016/0315598 A1
(43) Pub. Date: Oct. 27, 2016

(54) NOISE FILTER CIRCUIT

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: JIE MIN, Wuhan (CN); CHUN-SHENG CHEN, New Taipei (TW)

(21) Appl. No.: 14/716,583

(22) Filed: May 19, 2015

(30) Foreign Application Priority Data
Apr. 23, 2015 (CN) 201510196182.9

(51) Int. Cl. H03H 11/04

(52) U.S. Cl. CPC H03H 11/0405

(57) ABSTRACT

A noise filter circuit includes a first control circuit, a second control circuit, and a central processing unit (CPU). The first control circuit includes a first control terminal and a first output terminal. The second control circuit includes a second control terminal and a second output terminal. The CPU includes a clock signal input terminal electrically coupled to the second output terminal. The first control terminal receives a first voltage signal, the first output terminal being electrically coupled to the second control terminal, and the second control terminal receives a second voltage signal at a first voltage level. The first control circuit detects clock signals received by the CPU, the first control terminal receives a first voltage signal at a first voltage level when there are noise signals in the clock signals. The second output terminal is grounded to filter out the noise signals in the clock signals.

### CROSS-REFERENCE TO RELATED APPLICATIONS

This application claims priority to Chinese Patent Application No. 201510196182.9 filed on Apr. 23, 2015, the contents of which are incorporated by reference herein in its entirety.

### FIELD

The subject matter herein generally relates to a noise filtering.

### BACKGROUND

In electronics and particularly in computer electronics, central processing units (CPUs) are mounted to printed circuit boards, such as the motherboards of computers. Conventional CPUs may be adversely affected by noise when receiving clock signals.

### BRIEF DESCRIPTION OF THE DRAWINGS

Implementations of the present technology will now be described, by way of example only, with reference to the attached figures.

FIG. 1 is a block diagram of an embodiment of a noise signal filter circuit.

FIG. 2 is a circuit diagram of the noise signal filter circuit of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like. “Unit” means a collection of electronic hardware alone or in combination with software configured for a particular task or function, although units may overlap or share components.

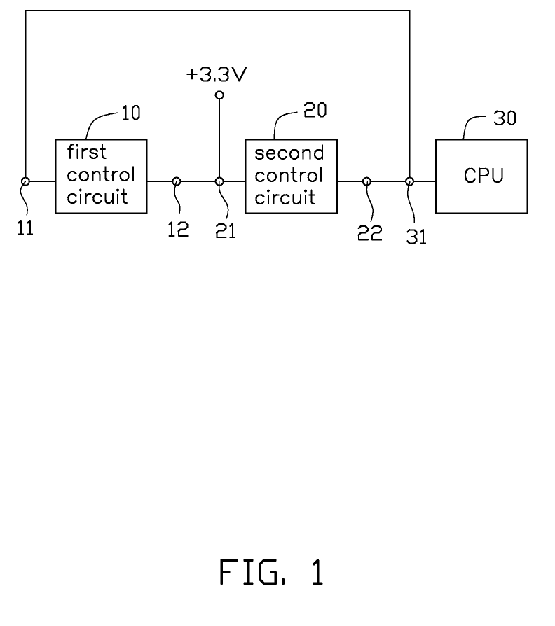

FIG. 1 illustrates a noise signal filter circuit in accordance with one embodiment. The noise signal filter circuit includes a first control circuit 10 and a second control circuit 20. The first control circuit 10 includes a first control terminal 11 and a first output terminal 12. The second control circuit 20 includes a second control terminal 21 and a second output terminal 22.

The first control terminal 11 is configured to receive a first voltage signal. The first output terminal 12 is electrically coupled to the second control terminal 21. The second control terminal 21 is configured to receive a second voltage signal at a high voltage level. The second output terminal 22 is electrically coupled to a clock signal input terminal 31 of a central processing unit (CPU) 30. The first control circuit 10 is configured to detect clock signals received by the CPU 30. The first control terminal 11 is configured to receive a first voltage signal at a low voltage level when there are noise signals in the clock signals. The second output terminal 22 is grounded to filter the noise signals out from the clock signals.

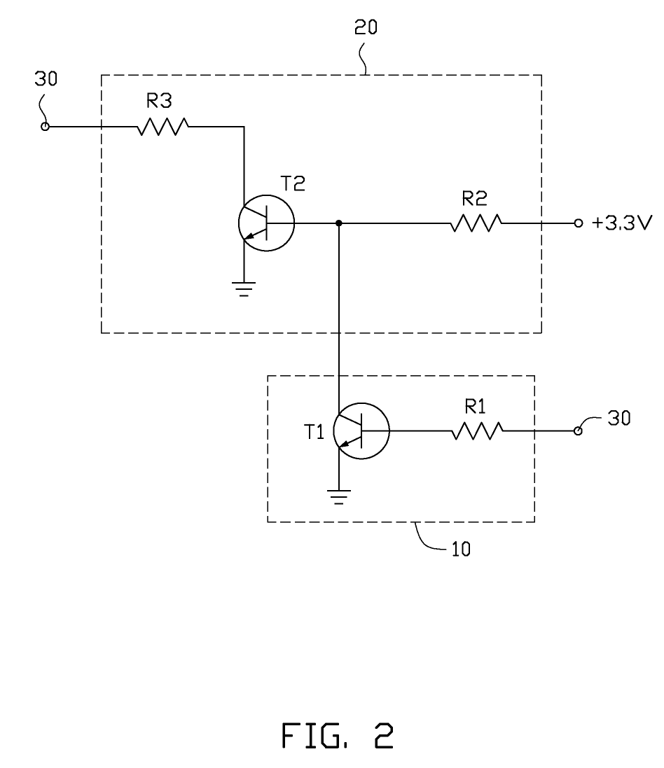

FIG. 2 illustrates that the first control circuit 10 includes a first switch T1 and a first resistor R1. The first switch T1 includes a first terminal, a second terminal, and a third terminal. The first terminal of the first switch T1 acts as the first control terminal 11 and is configured to receive the first voltage signal via the first resistor R1. The second terminal of the first switch T1 is grounded. The third terminal of the first switch T1 acts as the first output terminal 12. In at least one embodiment, the first switch T1 is an npn type transistor, and the first terminal, the second terminal, and the third terminal of the first switch T1 are base, emitter, and collector respectively.

The second control circuit 20 includes a second switch T2, a second resistor R2, and a third resistor R3. The second switch T2 includes a first terminal, a second terminal, and a third terminal. The first terminal of the second switch T2 is electrically coupled to the third terminal of the first switch T1. The first terminal of the second switch T2 acts as the second control terminal 21 and is configured to receive the second voltage signal of the high voltage level via the second resistor R2. The second terminal of the second switch T2 is grounded. The third terminal of the second switch T2 acts as the second output terminal 22 and is electrically coupled to the clock signal input terminal 31 via the third resistor R3. In at least one embodiment, the second switch T2 is an npn type transistor, and the first terminal, the second terminal, and the third terminal of the second switch T2 are base, emitter, and collector respectively. The second voltage signal is +3.3 volts.

In use, the first control circuit 10 can detect that there are noise signals in clock signals received by the CPU 30. The first terminal of the first switch T1 is configured to receive the first voltage signal at the low voltage level via the first resistor R1. The first switch T1 turns off. The first terminal of the second switch T2 is configured to receive the second voltage signal at the high voltage level via the second resistor R2. The second switch T2 turns on. The normal clock signals remain at a low voltage level. The noise signals in the clock signals remain at a high voltage level and are grounded via the second terminal of the second switch T2. Therefore, the noise signals in the clock signals are filtered out.

The embodiments shown and described above are only examples. Many details are often found in the art such as the other features of a noise signal filter circuit. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A noise signal filter circuit comprising:
a first control circuit comprising a first control terminal and a first output terminal;
a second control circuit comprising a second control terminal and a second output terminal; and
a central processing unit (CPU) comprising a clock signal input terminal electrically coupled to the second output terminal,
wherein the first control terminal is configured to receive a first voltage signal, the first output terminal is electrically coupled to the second control terminal, and the second control terminal is configured to receive a second voltage signal of a first voltage level, and wherein the first control circuit is configured to detect clock signals received by the CPU, the first control terminal is configured to receive a first voltage signal of a first voltage level in event the clock signals contain noise, and the second output terminal is grounded to filter the noise therefrom.

2. The noise signal filter circuit of claim 1, wherein the first control circuit comprises a first switch and a first resistor; the first switch comprises a first terminal, a second terminal, and a third terminal; the first terminal of the first switch acts as the first control terminal and is configured to receive the first voltage signal via the first resistor; the second terminal of the first switch is grounded; and the third terminal of the first switch acts as the first output terminal.

3. The noise signal filter circuit of claim 2, wherein the first switch is an npn type transistor; and the first terminal, the second terminal, and the third terminal of the first switch are base, emitter, and collector respectively.

4. The noise signal filter circuit of claim 2, wherein the second control circuit comprises a second switch, a second resistor, and a third resistor; the second switch comprises a first terminal, a second terminal, and a third terminal; the first terminal of the second switch is electrically coupled to the third terminal of the first switch; the first terminal of the second switch acts as the second control terminal and is configured to receive the second voltage signal of the high voltage level via the second resistor; the second terminal of the second switch is grounded; and the third terminal of the second switch acts as the second output terminal and is electrically coupled to the clock signal input terminal via the third resistor.

5. The noise signal filter circuit of claim 4, wherein the second switch is an npn type transistor, the first terminal, the second terminal, the third terminal of the second switch are base, emitter, and collector respectively, and the second voltage signal is +3.3 volts.

6. The noise signal filter circuit of claim 4, wherein when the first control circuit detects that there are noise signals in clock signals received by the CPU, the first terminal of the first switch is configured to receive the first voltage signal of the low voltage level via the first resistor, the first switch turns off, the first terminal of the second switch is configured to receive the second voltage signal of the high voltage level via the second resistor, the second switch turns on, the noise signals in the clock signals are grounded via the second terminal of the second switch, and the noise signals in the clock signals are filtered.

7. A noise signal filter circuit comprising:
a first control circuit comprising a first control terminal, a first output terminal, a first switch, and a first resistor;
a second control circuit comprising a second control terminal, a second output terminal, a second switch, and a second resistor; and
a central processing unit (CPU) comprising a clock signal input terminal electrically coupled to the second output terminal,
wherein the first control terminal is configured to receive a first voltage signal, the first output terminal is electrically coupled to the second control terminal, and the second control terminal is configured to receive a second voltage signal of a first voltage level, and
wherein the first control circuit is configured to detect clock signals received by the CPU, when the first control circuit detects that there are noise signals in clock signals received by the CPU, the first terminal of the first switch is configured to receive the first voltage signal of the low voltage level via the first resistor, the first switch turns off, the first terminal of the second switch is configured to receive the second voltage signal of the high voltage level via the second resistor, the second switch turns on, the noise signals in the clock signals are grounded via the second terminal of the second switch, and the noise signals in the clock signals are filtered.

8. The noise signal filter circuit of claim 7, wherein the first switch comprises a first terminal, a second terminal, and a third terminal; the first terminal of the first switch acts as the first control terminal and is configured to receive the first voltage signal via the first resistor; the second terminal of the first switch is grounded; and the third terminal of the first switch acts as the first output terminal.

9. The noise signal filter circuit of claim 8, wherein the first switch is an npn type transistor; and the first terminal, the second terminal, and the third terminal of the first switch are base, emitter, and collector respectively.

10. The noise signal filter circuit of claim 8, wherein the second control circuit further comprises a third resistor; the second switch comprises a first terminal, a second terminal, and a third terminal; the first terminal of the second switch is electrically coupled to the third terminal of the first switch; the first terminal of the second switch acts as the second control terminal and is configured to receive the second voltage signal of the high voltage level via the second resistor; the second terminal of the second switch is grounded; and the third terminal of the second switch acts as the second output terminal and is electrically coupled to the clock signal input terminal via the third resistor.

11. The noise signal filter circuit of claim 10, wherein the second switch is an npn type transistor, the first terminal, the second terminal, the third terminal of the second switch are base, emitter, and collector respectively, and the second voltage signal is +3.3 volts.
